(19) United States
(12) Patent Application Publication
(10) Pub. No.: US 2010/0243605 A1
(43) Pub. Date: Sep. 30, 2010

(54) ETCHING METHOD, ETCHING APPARATUS, COMPUTER PROGRAM AND STORAGE MEDIUM

(75) Inventor: Tetsuya Nishizuka, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/438,588

(22) PCT Filed: Aug. 21, 2007
(86) PCT No.: PCT/JP07/66189

§ 371 Date: Feb. 24, 2009

(30) Foreign Application Priority Data
Aug. 25, 2006 (JP) 2006-228989

(51) Int. Cl. H01L 21/3065

(52) U.S. Cl. 216/67; 156/345.28

(57) ABSTRACT

Disclosed is an etching method for performing an etching process on an etching target film, which has a dielectric constant smaller than that of a SiO₂ film and is formed on a surface of a target object. The etching method includes: mounting the target object on a mounting table in a processing vessel configured to be evacuable; supplying a predetermined etching gas into the processing vessel and converting the etching gas into plasma; and applying a high frequency power of a preset frequency to the mounting table as a bias power under the presence of the etching gas in plasma state. The step of applying the high frequency power includes: a first step of applying a high frequency power of a first frequency as the bias power; and a second step of applying a high frequency power of a second frequency different from the first frequency as the bias power.

### CROSS-REFERENCES TO RELATED APPLICATIONS

This application claims the benefit of Japanese Patent Application No. 2006-228989, filed on Aug. 25, 2006, which is hereby incorporated by reference in its entirety.

### TECHNICAL FIELD

The present invention relates to an etching method and an etching apparatus; and, more particularly, to an etching method and an etching apparatus for forming a hole portion (hole) such as a through hole or a via hole, or a groove portion (trench) in a surface of a target object such as a semiconductor wafer or the like. Further, the present invention also pertains to a computer program for executing the etching method on the etching apparatus and a storage medium storing the computer program therein.

### BACKGROUND ART

In general, in order to manufacture a semiconductor device, various kinds of processes such as a film forming process, a pattern etching and the like are repeatedly performed on a semiconductor wafer to manufacture a desired device. However, to meet a demand for a higher level of integration and miniaturization of the semiconductor device, a line width or a diameter of a hole (hole portion) is getting more miniaturized. Further, along with such trend, various kinds of laminated films are getting thinner, and an interlayer dielectric, for example, is not an exception. Newly proposed as such interlayer dielectric is a material film having smaller thickness than that used in the conventional semiconductor device but having the same level of insulation property, i.e., having a so-called low-k (low dielectric constant) characteristic. Such material film may be, for example, a porous SiOC or SiOCH film, or a CF film (also referred to as a fluorine-containing carbon film or a non-crystalline carbon film), or the like. Conventionally, a SiO₂ film generally employed as an interlayer dielectric has a dielectric constant (relative dielectric constant) of about 3.8, whereas the SiOC film, the SiOCH film and the CF film mentioned above have a dielectric constant ranging from, e.g., about 2.0 to 2.8, which is smaller than that of the SiO₂ film. Hereinafter, such material having the small dielectric constant will be referred to as a low-k material.

Furthermore, to keep up with such trend of miniaturization, there has been a requirement for the enhancement of the optical resolution of photoresist used as a mask material in an etching process, and a photoresist material suitable for a new ArF laser has been proposed to meet such requirement.

The process of performing an etching process on the semiconductor wafer generally involves the steps of activating an etching gas by making it to be excited by using plasma; and etching an etching target film into a preset pattern by acting the activated etching gas on a wafer surface having a pattern mask formed thereon. At this time, a high frequency power of a predetermined RF may be applied to a mounting table mounting the wafer thereon as a bias power when necessary, so that ions generated by the plasma can be implanted into the wafer surface, and the etching can be performed efficiently (see, for example, Japanese Patent Laid-open Publication Nos. H6-122983, H7-226393 and 2000-164573).

In the meantime, recess portions to be formed by the etching include a recess portion of a hole shape such as a through hole or a via hole, and a recess portion of an elongated narrow groove (trench) shape for forming a narrow wiring, and these hole portion and groove portion are formed to coexist on the wafer surface. During the etching, though an etching stopper film is formed under the etching target film, it is desirable that bottoms of the hole portion and groove portion reach the etching stopper film approximately at the same time, if considering the resistance of the etching stopper film against the etching gas.

To this end, since the SiO₂ film generally employed as the interlayer dielectric is very hard and dense, the etching process is performed by setting a bias power to have a high power level of, e.g., about 1000 W and a Vpp (peak-to-peak voltage) of a high frequency bias power to have a high voltage level of, e.g., about 2000 V, whereby the etching can be performed such that the bottoms of the hole portion and the groove portion reach the etching stopper film almost simultaneously. In such case, to suppress a plasma damage on the wafer, it has been performed to change the frequency of the bias power during the etching (see, for example, Japanese Patent Laid-open Publication No. H6-122983).

However, as the etching target film is changed from the hard and dense SiO₂ film to the above-mentioned comparatively flexible low-k material, and a groove width and a hole diameter are further miniaturized to be no greater than about 65 nm, it is impossible to use the above-described etching method as it is.

This point will be explained in further detail with reference to FIGS. 8A to 8C. FIGS. 8A to 8C are enlarged cross-sectional perspective views showing states when etching an interlayer dielectric formed on a semiconductor wafer. FIG. 8A illustrates a state in which a patterned mask is formed on the interlayer dielectric; FIG. 8B illustrates a state during the etching; and FIG. 8C illustrates a state after the completion of the etching.

As shown in FIG. 8A, an etching stopper film 2 serving as an underlying film is formed on a semiconductor wafer S, and, for example, an interlayer dielectric 4 is formed thereon as an etching target film. Further, a patterned mask 6 is formed on the interlayer dielectric 4 over the entire surface thereof. The mask 6 is provided with a groove pattern 6A corresponding to a portion where a groove portion is to be formed and a hole pattern 6B corresponding to a portion where a hole portion is to be formed. A width of the groove portion (groove width) and a diameter of the hole portion (hole diameter) are very small due to the trend of miniaturization, and recently, a size no greater than, e.g., about 65 nm is required. The etching stopper film 2 is made of, e.g., a SiC film, and the interlayer dielectric 4 is formed of a thin film made of the aforementioned low-k material, e.g., the material selected from a SiOC film, a SiOCH film, a CF film and the like.

If the etching is performed on the semiconductor wafer S, the interlayer dielectric 4 is gradually removed, and a groove portion 8A and a hole portion 8B corresponding to the pattern of the mask 6 are gradually formed, as illustrated in FIG. 8B. Then, as shown in FIG. 8C, when bottoms of the groove portion 8A and the hole portion 8B finally reach the underlying etching stopper film 2, the etching is completed. Here, the groove portion 8A may be a trench, and the hole portion 8B may be a via hole, a contact hole or the like.

During the etching, an etching gas is supplied into a processing vessel kept in a vacuum state and activated by plasma, and ions are implanted into the wafer by applying a bias power of a high frequency power to the wafer, so that the etching is performed efficiently.

However, in consideration of the above-mentioned fact that the resistance of the etching stopper film 2 against the etching gas is not so high, it is desirable that the bottoms of the groove portion 8A and the hole portion 8B reach the etching stopper film 2 approximately, i.e., substantially at the same time. However, as for the etching target film made of the low-k film which is more flexible than the SiO₂ film, the etching speed largely depends on the frequency of the bias power, the sizes of the groove portion 8A and the hole portion 8B, and the like. Thus, it has been very difficult to control the etching such that the bottoms of the groove portion 8A and the hole portion 8B reach the etching stopper film 2 approximately simultaneously.

For example, as shown in FIG. 8B, a ratio (H/L) between the depth L of the groove portion 8A and the depth H of the hole portion 8B during the etching does not become a value of 1 but becomes smaller or larger than 1.

When etching a tungsten film formed by a blanket CVD, though there has been proposed changing the frequency of the bias power from about 13.56 MHz to about 800 kHz or vice versa during the etching, as disclosed in paragraphs [0040] to [0042] of Japanese Patent Laid-open Publication No. H7-226393, it is impossible to apply this method directly to the etching of the thin film of the low-k material which is different from the tungsten film.

In the view of the foregoing, the present invention has been conceived to efficiently solve the above-mentioned problems. The object of the present invention is to provide an etching method, an etching apparatus, a computer program and a storage medium, capable of allowing bottoms of a groove portion (trench) and a hole portion (hole) formed during the etching to reach an etching stopper film substantially simultaneously.

### DISCLOSURE OF THE INVENTION

In accordance with the present invention, there is provided an etching method for performing an etching process on an etching target film, which has a dielectric constant smaller than that of a SiO₂ film and formed on a surface of a target object, the method including: mounting the target object on a mounting table in a processing vessel configured to be evacuable; supplying a predetermined etching gas into the processing vessel and converting the etching gas into plasma; and applying a high frequency power of a preset frequency to the mounting table as a bias power under the presence of the etching gas in plasma state, wherein the step of applying the high frequency power as the bias power includes: a first step of applying a high frequency power of a first frequency as the bias power; and a second step of applying a high frequency power of a second frequency different from the first frequency as the bias power.

As described, since the etching process is performed in two steps including the first step of performing the etching by applying the high frequency power of the first frequency as the bias power and the second step of performing the etching by applying the high frequency power of the second frequency, which is different from the first frequency, as the bias power, the bottoms of the groove portion (trench) and the hole portion (hole) formed during the etching are allowed to reach the etching stopper film approximately at the same time.

At this time, for example, it is desirable that a combination of the first frequency and the second frequency is a combination of a frequency equal to or smaller than about 2 MHz and a frequency greater than about 2 MHz. In addition, for example, it is desirable that a combination of the first frequency and the second frequency is a combination of two kinds of frequencies selected from a group consisting of about 400 kHz, 2 MHz and 13.56 MHz, and the combination of frequencies includes the 400 kHz. Further, for example, it is desirable that one of the first and second steps is performed first and then the other step is performed.

Further, for example, it is desirable that the high frequency power has a power equal to or less than about 300 W, and a Vpp (peak-to-peak voltage) of the high frequency powers of the first and second frequencies is equal to or less than about 560 V. Furthermore, for instance, it is desirable that the etching gas is a CF-based gas, and the etching gas contains at least one selected from a group consisting of CF₄, C₂F₆, C₃F₈ and CHF₃.

Furthermore, for example, it is desirable that the etching target film formed on the surface of the target object is formed of an interlayer dielectric, and a mask, which is provided with a pattern for forming a groove portion and a hole portion in the interlayer dielectric, is provided on the interlayer dielectric. Further, for example, it is desirable that the hole portion has a transversal cross section of a circular shape, and a width of the groove portion and a diameter of the hole portion are not greater than about 65 nm.

Moreover, for example, it is desirable that an etching stopper film is formed under the interlayer dielectric, and conditions are set up such that bottoms of the groove portion and the hole portion being formed in the interlayer dielectric reach the etching stopper film substantially at the same time. Further, for example, it is desirable that the interlayer dielectric is formed of a film selected from a group consisting of a SiOC film, a SiOCH film and a CF film. Further, for example, it is desirable that the interlayer dielectric is formed of a film selected from a group consisting of a SiOC film, a SiOCH film and a CF film, and the etching stopper film is formed of a SiC film.

Further, for example, when applying the high frequency power of the frequency of about 400 kHz as the bias power, it is desirable that a power of the high frequency power is equal to or less than about 300 W. Further, for example, it is desirable that the frequency of the bias power in the other step performed later is higher than the frequency of the bias power in the one step performed first. Furthermore, for instance, it is desirable that the conditions are set up such that the bottoms of the groove portion and the hole portion being formed in the interlayer insulating film reach the etching stopper film approximately at the same time by performing one of the first and second steps first and then performing the other step and by switching from the one step to the other step at an appropriate timing.

In accordance with the present invention, there is provided an etching apparatus including: a processing vessel incorporating therein a mounting table for mounting thereon a target object having an etching target film, which has a dielectric constant smaller than that of a SiO2 film, formed on a surface thereof; a gas exhaust system for evacuating the inside of the processing vessel; a gas supply unit for supplying an etching gas into the processing vessel; a plasma generating unit for generating plasma in the processing vessel; a high frequency bias power supply unit for supplying a high frequency power of a first frequency and a high frequency power of a second frequency different from the first frequency as a bias power to the mounting table; and a control unit for controlling the high frequency bias power supply unit, wherein the control unit controls the high frequency bias power supply unit such that the high frequency bias power supply unit performs: a first process of applying the high frequency power of the first frequency as the bias power; and a second process of applying the high frequency power of the second frequency different from the first frequency as the bias power.

In accordance with the present invention, there is provided a computer program for executing an etching method, on a computer, for performing an etching process on an etching target film, which has a dielectric constant smaller than that of a SiO2 film and formed on a surface of a target object, the method including: mounting the target object on a mounting table in a processing vessel configured to be evacuable; supplying a predetermined etching gas into the processing vessel and converting the etching gas into plasma; and applying a high frequency power of a preset frequency to the mounting table as a bias power under the presence of the etching gas in plasma state, wherein the step of applying the high frequency power as the bias power includes: a first step of applying a high frequency power of a first frequency as the bias power; and a second step of applying a high frequency power of a second frequency different from the first frequency as the bias power.

In accordance with the present invention, there is provided a storage medium for storing therein a computer program for executing an etching method, on a computer, for performing an etching process on an etching target film, which has a dielectric constant smaller than that of a SiO2 film and formed on a surface of a target object, the method including: mounting the target object on a mounting table in a processing vessel configured to be evacuable; supplying a predetermined etching gas into the processing vessel and converting the etching gas into plasma; and applying a high frequency power of a preset frequency to the mounting table as a bias power under the presence of the etching gas in plasma state, wherein the step of applying the high frequency power as the bias power includes: a first step of applying a high frequency power of a first frequency as the bias power; and a second step of applying a high frequency power of a second frequency different from the first frequency as the bias power.

According to the etching method, the etching apparatus, the computer program and the storage medium in accordance with the present invention, advantageous effects as follows can be obtained. Since the etching process is performed in two steps including the first step of performing the etching by applying the high frequency power of the first frequency as the bias power and the second step of performing the etching by applying the high frequency power of the second frequency, which is different from the first frequency, as the bias power, the bottoms of the groove portion (trench) and the hole portion (hole) formed during the etching are allowed to reach the etching stopper film approximately at the same time.

### BRIEF DESCRIPTION OF THE DRAWINGS

FIG. 1 is a configuration view to illustrate an example of an etching apparatus in accordance with the present invention;

FIGS. 2A to 2B are explanatory diagrams to illustrate each process of an etching method in accordance with the present invention;

FIGS. 3A and 3B are schematic diagrams to describe a relationship between a depth of a hole (hole portion) and a depth of a trench (groove portion);

FIGS. 4A and 4B provide diagrams to describe a dependency of an etching depth ratio (H/L) upon a frequency of a bias power with respect to a hole diameter (hole width) during an etching;

FIG. 5 is a graph showing a relationship between a frequency of a bias power and a Vpp when the bias power is kept constant;

FIG. 6 is a graph showing a relationship between a bias power, a selectivity against a photoresist, and a frequency of the bias power;

FIG. 7 sets forth a graph showing ion energy distributions of bias powers of about 400 kHz and 2 MHz; and

FIGS. 8A to 8C are an enlarged cross-sectional perspective view to describe a state when etching an interlayer dielectric formed on a semiconductor wafer.

### BEST MODE FOR CARRYING OUT THE INVENTION

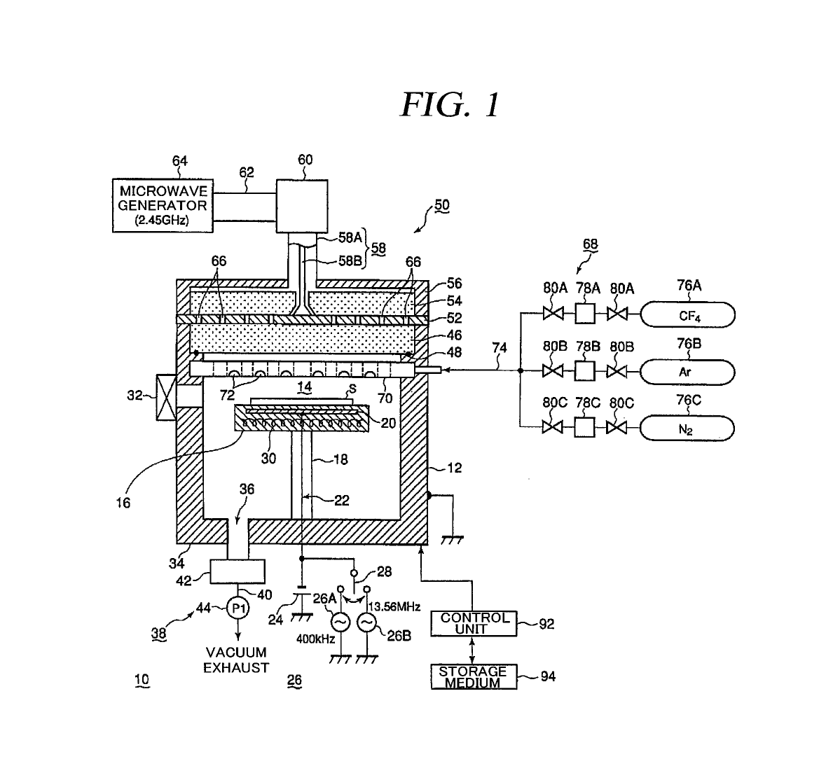

Hereinafter, an etching method, an etching apparatus, a computer program and a storage medium in accordance with an embodiment of the present invention will be described with reference to the accompanying drawings. FIG. 1 is a configuration view of the etching apparatus in accordance with the present invention. As shown in FIG. 1, the etching apparatus 10 includes a processing vessel 12 formed in a cylindrical shape as a whole, and a sidewall and a bottom portion of the processing vessel 12 are made of a conductor such as aluminum or the like. An inside of the processing vessel 12 is configured as an airtightly sealed processing space 14, and plasma is generated in this processing space 14. The processing vessel 12 itself is grounded.

Disposed inside the processing vessel 12 is a mounting table 16 of a circular plate shape, for mounting a target object to be processed, e.g., a semiconductor wafer S, on a top surface thereof. Specifically, the mounting table is of a flat circular plate shape made of a heat resistant material, for example, ceramic such as alumina or the like, and is sustained on the bottom portion of the processing vessel via a supporting column 18 made of, e.g., aluminum or the like.

Disposed on the top surface of the mounting table 16 is a thin electrostatic chuck 20 having therein a conductor line arranged in, e.g., a mesh shape, and the semiconductor wafer S placed on the mounting table 16, specifically, on the electrostatic chuck 20 can be attracted to and firmly held on the electrostatic chuck 20 itself by an electrostatic attracting force. The conductor line of the electrostatic chuck 20 is connected to a DC power supply 24 via a wiring 22 to exert the electrostatic attracting force. Further, the wiring 22 is connected to a high frequency bias power supply unit 26 for supplying a high frequency power of a preset RF to the mounting table 16 as a bias power.

Specifically, the high frequency bias power supply unit 26 includes a first high frequency power supply 26A for supplying a high frequency power of a first frequency and a second high frequency power supply 26B for supplying a high frequency power of a second frequency different from the first frequency, and these two kinds of high frequency powers can be selectively supplied to the mounting table 16 by using a changeover switch 28. Here, for example, about 400 kHz and about 13.56 MHz are used as the first frequency and the second frequency, respectively. Further, as necessary, it is also possible to use a high frequency power supply of about 2 MHz as the first frequency instead of the high frequency power supply of about 400 kHz. Moreover, installed inside the mounting table 16 is a heating unit 30 made of a resistance heater, for heating the wafer S if necessary.

Further, the mounting table 16 is provided with a plurality of, e.g., three elevating pins (not illustrated) for moving the wafer S up and down when loading and unloading it. In addition, provided at the sidewall of the processing vessel 12 is a gate valve 32 opened and closed when loading and unloading the wafer S to and from the inside of the processing vessel 12, and a gas exhaust port 36 is provided in a vessel bottom portion 34 to exhaust an atmosphere inside the vessel.

A gas exhaust system 38 is connected to the gas exhaust port 36 to exhaust the atmosphere inside the processing vessel 12. Specifically, the gas exhaust system 38 has a gas exhaust passage 40 connected to the gas exhaust port 36. A pressure control valve 42 made of, for example, a gate valve, is installed at an utmost upstream side of the gas exhaust passage 40, and a vacuum pump 44 is disposed at a downstream side thereof.

Moreover, a ceiling portion of the processing vessel 12 is opened, and a ceiling plate 46, which is made of, for example, quartz or a ceramic material such as Al₂O₃ and has a microwave transmission property, is airtightly provided at the opening via a seal member 48 such as an O ring. A thickness of the ceiling plate 46 is set to be, for example, about 20 mm in consideration of a pressure resistance.

Disposed on a top surface of the ceiling plate 46 is a plasma generating unit 50 for generating plasma in the processing vessel 12. Specifically, the plasma generating unit 50 has a circular plate shaped planar antenna member 52 disposed on the top surface of the ceiling plate 46, and a slow wave member 54 is disposed on the planar antenna member 52. The slow wave member 54 has a high-k property to shorten a wavelength of the microwave. The planar antenna member 52 is configured as a bottom plate of a waveguide box 56 made of a conductive vessel of a hollow cylinder shape covering the entire surface of a top portion of the slow wave member 54, and is provided to face the mounting table 16 inside the processing vessel 12.

Peripheral portions of the waveguide box 56 and the planar antenna member 52 are electrically connected with the processing vessel 12. Further, an external tube 58A of a coaxial waveguide 58 is connected to a center of the top portion of the waveguide box 56, and an internal conductor 58B is connected to a central portion of the planar antenna member 52 via a through hole provided in a center of the slow wave member 54. The coaxial waveguide 58 is connected to a microwave generator 64, for generating a microwave of, e.g., about 2.45 GHz and having a matching circuit (not shown), via a mode converter 60 and a waveguide 62. The coaxial waveguide 58 propagates the microwave to the planar antenna member 52.

The planar antenna member 52 is made of an aluminum or copper plate whose surface is plated with silver, and a number of microwave radiation holes 66 arranged as, for example, elongated through holes are formed in this circular plate. The arrangement of the microwave radiation holes 66 is not limited to a specific pattern. For instance, they can be arranged in concentric, spiral or radial pattern.

Further, a gas supply unit 68 for supplying a necessary etching gas and so forth into the processing vessel 12 is connected thereto. To elaborate, the gas supply unit 68 includes a gas injection unit 70 disposed above the mounting table 16 in the processing vessel 12. The gas injection unit 70 is configured as a shower head made by arranging a gas flow path made of, for example, quartz in a grid pattern and by forming a number of gas injection holes 72 in the gas flow path. The gas injection unit 70 is connected with a gas flow path 74. An end portion of the gas flow path 74 is branched into a plurality of, e.g., three branch lines, and gas sources 76A, 76B and 76C are connected to the respective branch lines.

Specifically, stored in the gas source 76A is an etching gas; stored in the second gas source 76B is a plasma gas, e.g., an Ar gas; and stored in the third gas source 76C is, e.g., an N₂ gas for use in the purge of the vessel. Further, instead of the gas sources 76A to 76C, or in addition to the gas sources 76A to 76C, other gas sources can be connected thereto, if necessary.

Here, a CF-based gas is used as the etching gas. As the etching gas, it is desirable to use at least one gas selected from a group including CF₄, C₃F₈, CHF₃, and C₂F₆. Here, as the etching gas, the CF₄ gas is used, for instance.

On each branch line, flow rate controllers 78A to 78C such as mass flow controllers controlling gas flow rates flowing each branch line are installed on each branch line. Disposed at upstream and downstream of the respective flow rate controllers 78A to 78C are opening/closing valves 80A to 80C, so that a flow rate of each gas can be controlled as required, including the start and stop of the supply of each gas.

The whole operation of the etching apparatus 10 is controlled by a control unit 92 made up of, e.g., a microcomputer or the like. A computer program for executing the operation is stored in a storage medium 94 such as a flexible disk, a CD (Compact Disk), a HDD (Hard Disk Drive), a flash memory, or the like. Specifically, a supply of each gas, a control of their flow rates, a supply of a microwave or a high frequency bias wave, a control of power thereof, a control of switching of high frequency bias powers, a control of a processing temperature or pressure, and the like are performed by instructions from the control unit 92.

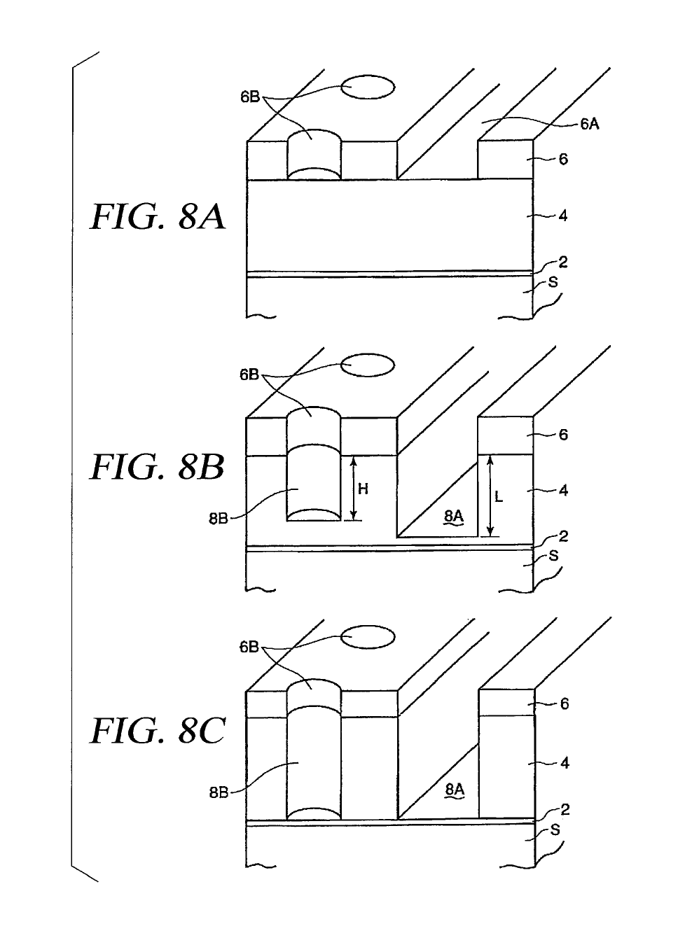

Below, an etching method, which is performed by using the etching apparatus 10 having the above-described configuration, will be explained. To explain a general operation, the semiconductor wafer S is first loaded into the processing vessel 12 by a transfer arm (not shown) through the gate valve 32. By moving the non-illustrated elevating pins up and down, the wafer S is placed on a mounting surface on the top surface of the mounting table 16. Then, the wafer S is electrostatically attracted and held by the electrostatic chuck 20. On the top surface of the wafer S, a patterned mask 6 as shown in FIG. 8A is already formed. That is, as illustrated in FIG. 8A, formed on the semiconductor wafer S is an etching stopper film 2 serving as an underlying film, and formed thereon is an interlayer dielectric 4 which is an etching target film. The patterned mask 6 is formed on an entire surface of the interlayer dielectric 4. The interlayer dielectric 4 is made of, a low-k material, and the etching stopper film 2 is formed of a SiC film. Further, the mask 6 is provided with a groove pattern 6A corresponding to a portion where a groove portion is to be formed and a hole pattern 6B corresponding to a portion where a hole portion is to be formed. Each of a width of the groove pattern 6A and a diameter of the hole pattern 6B is set to be, e.g., about 65 nm or smaller.

The wafer S is maintained at a preset processing temperature when the heating unit is installed in the mounting table 16, and a necessary processing gas, for example, each of the predetermined etching gas, the Ar gas and the like is injected and supplied into the processing vessel 12 from the gas injection holes 72 of the gas injection unit 70 made of the shower head via the gas flow path 74 of the gas supply unit 68 at a certain flow rate. At this time, the vacuum pump 44 of the gas exhaust system 38 is operated, and the inside of the processing vessel 12 is maintained at a preset processing pressure by controlling the pressure control valve 42. At the same time, the microwave generator 64 of the plasma generating unit 50 is operated, and a microwave generated by the microwave generator 64 is supplied to the planar antenna member 52 via the waveguide 62 and the coaxial waveguide 58. The microwave is then introduced into the processing space 14 after its wavelength is shortened by the slow wave member 54, whereby plasma is generated in the processing space 14, and an etching process is performed by using the plasma.

If the microwave is introduced into the processing vessel 12 from the planar antenna member 52, each gas is converted into plasma and activated by the microwave. By active species generated at that time, an etching by the plasma is performed on the surface of the wafer S. At this time, a high frequency power of a certain selected frequency is applied from the high frequency bias power supply unit 26 to the mounting table 16 (electrostatic chuck 20) via the wiring 22 as the bias power, whereby ionized active species can be implanted into the wafer surface with a high directionality.

Here, the etching method of the present invention includes a first process of performing an etching by applying a high frequency power of a first frequency as a bias power and a second process of performing an etching by applying a high frequency power of a second frequency, which is different from the first frequency, as a bias power. Further, here, a CF₄ gas is used as the etching gas through the first and second processes.

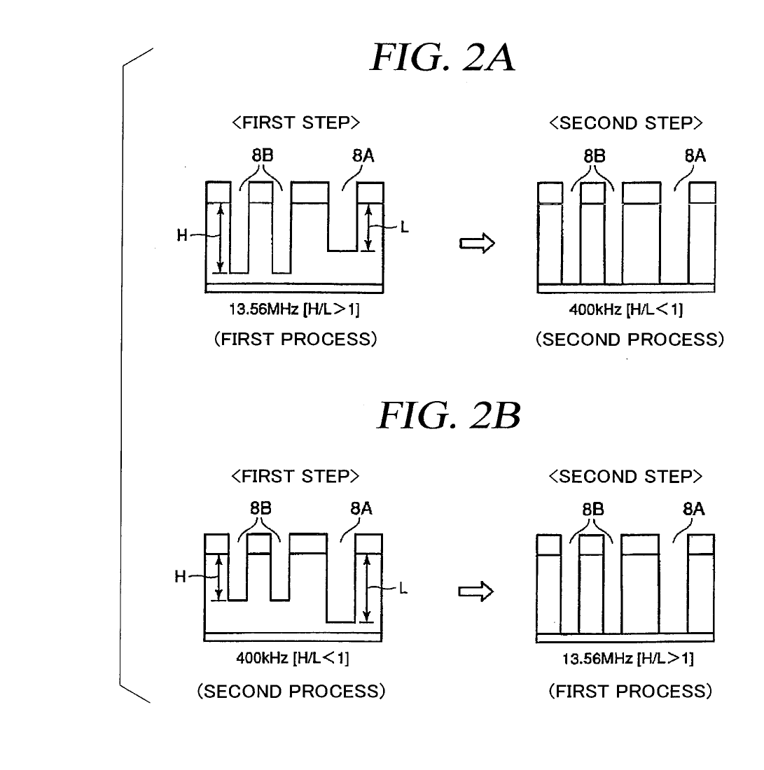

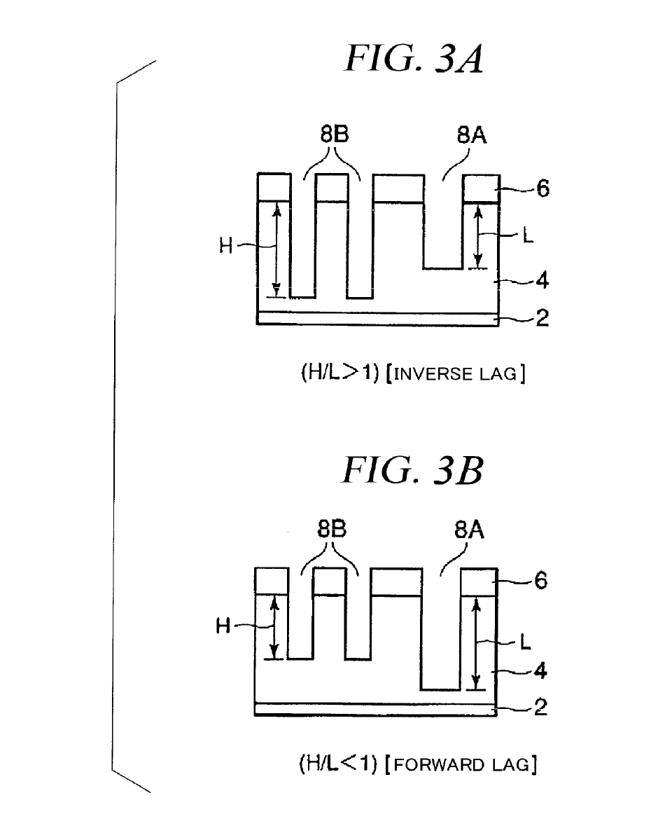

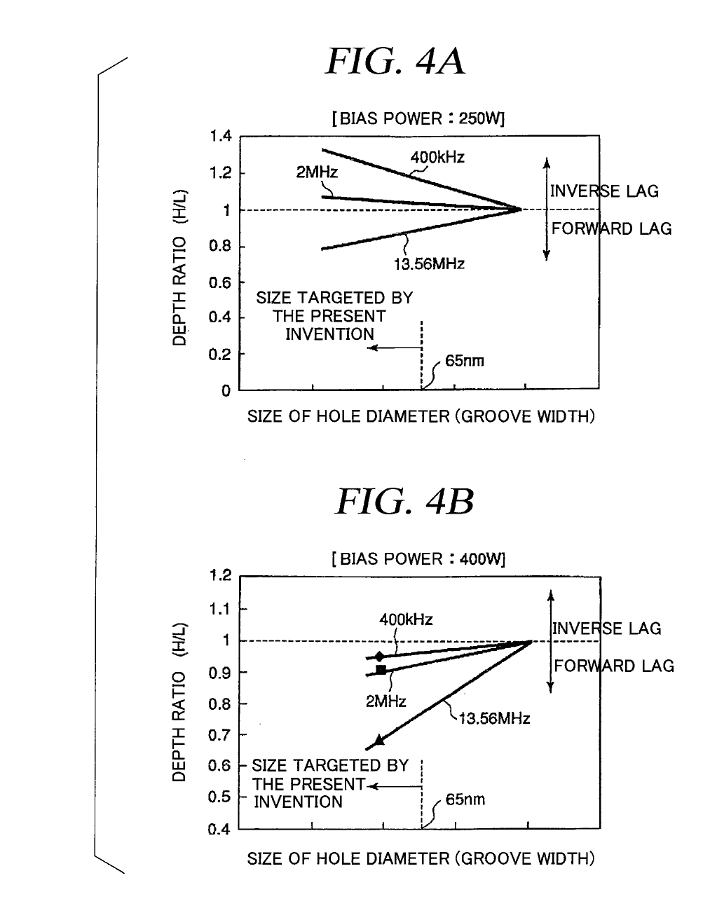

FIGS. 2A and 2B are explanatory diagrams for describing each process of the etching method of the present invention; FIGS. 3A and 3B are schematic diagrams for describing a relationship between the depths of a hole (hole portion) and a trench (groove portion); and FIGS. 4A and 4B are charts for describing a dependency of an etching depth ratio (H/L) upon a frequency of the bias power with respect to a hole diameter (groove width) during the etching. As shown in FIG. 2A, in a first step of the method in accordance with the present invention, the etching of the first process is performed by using, e.g., the CF₄ gas as the etching gas and the bias power having a frequency of about 13.56 MHz. At this time, a depth ratio (H/L) between the hole and the trench becomes ‘H/L>1’ (hereinafter, this state is also referred to as ┌inverse Lag┘).

Then, in a second step, the etching of the second process is performed by using the same CF₄ gas as the etching gas, while changing the frequency of the bias power from 13.56 MHz to about 400 kHz. At this time, the depth ratio (H/L) between the hole and the trench becomes ‘H/L<1’, and, resultantly, the delay of the etching of a trench 8A in the first step is recovered, so that bottoms of the trench 8A and a hole 8B are allowed to reach the etching stopper film 2 approximately at the same time. That is, since there exist two different occasions that the depth ratio (H/L) becomes ‘H/L>1’ and ‘H/L<1’ depending on the frequency of the bias power, it is possible to combine both cases, to thereby carry out the etching such that the respective bottoms of the hole 8B and the trench 8A reach the etching stopper film 2 approximately simultaneously as mentioned above.

As described, since it is possible to combine the first and second processes, it may be possible to perform the first and second processes in the reverse order. That is, as shown in FIG. 2B, the second process is performed as the first step. At this time, the depth ratio (H/L) becomes ‘H/L<1’ (hereinafter, this state is also referred to as a ┌forward Lag┘. Then, as the second step, the first process is performed by changing the frequency of the bias power to about 13.56 MHz.

In this case, it is also possible to perform the etching so that the respective bottoms of the hole 8B and the trench 8A reach the etching stopper film 2 approximately at the same time, as in the case shown in FIG. 2A. Here, as will be described later, in order to increase a selectivity of the interlayer dielectric 4 against the etching stopper film 2, it is desirable to set ion energy to be small by lowering a Vpp (peak-to-peak voltage) of the bias power when the bias power is kept constant. Accordingly, it is desirable to set the frequency of the bias power to be higher in the second step. For this reason, the method shown in FIG. 2B using the frequency of about 13.56 MHz in the second step is more desirable.

Further, as will be described later, since the mask 6 has a great resistance against the frequency of about 400 kHz of the bias power and becomes hard to be removed by the etching gas, it is desirable to use the high frequency power of about 400 kHz as the bias power in either one of the first and second steps. In such case, as first and second frequencies, a combination of two kinds selected from a group including about 400 kHz, 2 MHz and 13.56 MHz is employed, and it is desirable that such combination always includes the 400 kHz.

Further, since the etching target film is not a hard and dense SiO₂ film but a relatively flexible low-k material, e.g., a porous SiOC film or the like, the bias power is set to be much smaller than 1000 W used for the SiO₂ film, for example, it is set to be about 300 W or below. Further, because the Vpp of this bias power becomes a maximum value, e.g., about 560 V when the frequency of the bias power is 400 kHz, the bias power is set to be not greater than such value. If the bias power exceeds 300 W, an etching rate for the low-k film becomes excessively great, so that it becomes difficult to perform a control of ‘forward Lag’ and ‘inverse Lag’, failing to allow the bottoms of the hole portion (hole) and the groove portion (trench) to reach the etching stopper film approximately at the same time. Further, the resistance of the photoresist material forming the mask 6, i.e., the selectivity is deteriorated. In this case, it is desirable to set the bias power to be equal to or greater than about 200 W to obtain an etching rate over a certain level.

Further, as for specific values of the hard and dense SiO₂ film and the relatively flexible low-k material, a modulus of the SiO₂ film is equal to or greater than about 70 GPa, whereas a modulus of the low-k material is equal to or smaller than about 10 GPa. Here, the modulus refers to a limit value of elasticity when a stress is applied to a film, and when a value exceeds the modulus, it implies that the film would suffer a plastic deformation or be damaged.

Since characteristics that become a basis of the method of the present invention have been investigated, an investigated result will be explained with reference to FIGS. 4A and 4B. FIGS. 4A and 4B are graphs showing the dependency of the etching depth ratio (H/L) upon the frequency of the bias power with respect to the hole diameter (groove width) during the etching. FIG. 4A shows a characteristic when the bias power is kept constant at about 250 W, while FIG. 4B shows a characteristic when the bias power is maintained constant at about 400 W. A horizontal axis of each graph indicates a size of the hole diameter (groove width), while a vertical axis represents the depth ratio (H/L) between the hole and the trench. Accordingly, in FIGS. 4A and 4B, a region above H/L=1 becomes an inverse Lag region (see FIG. 3A), while a region below H/L=1 becomes a forward Lag region (see FIG. 3B). In addition, the left region of the horizontal axis corresponds to a size of the hole diameter (groove width) targeted by the present invention, i.e., 65 nm or below. Further, as the bias power, the high frequency powers of three kinds of frequencies of about 400 kHz, 2 MHz and 13.56 MHz are examined.

In both of the FIGS. 4A and 4B, when the size of the hole diameter or the like exceeds a certain level, for example, about 150 nm, the depth ratio (H/L) becomes about ‘1’ without depending on the frequency of the bias power. However, as the hole diameter (groove width) decreases, the etching depth is deepened along with the decrease of the frequency of the bias power.

That is, as shown in FIG. 4B, when the bias power is great (400 W), though the depth ratio (H/L) shows a stronger forward Lag tendency as the frequency increases, the depth ratio (H/L) becomes not greater than 1 without depending on the frequency of the bias power and always stays in the forward Lag state, in the region where the hole diameter (groove width) is equal to or less than about 65 nm. That is, when the bias power is great, it implies that the bottoms of the hole portion (hole) and the groove portion (trench) cannot reach the etching stopper film approximately at the same time even if the frequency of the bias power is changed during the etching.

To the contrary, as illustrated in FIG. 4A, when the bias power is small (250 W), the depth ratio (H/L) becomes greater than 1 when the frequency of the bias power is about 400 kHz and 2 MHz, while it becomes smaller than 1 when the frequency of the bias power is about 13.56 MHz, in the region where the hole diameter (groove width) is equal to or below 65 nm.

Accordingly, to allow the bottoms of the hole portion (hole) and the groove portion (trench) to reach the etching stopper film approximately at the same time, it can be seen that it is desirable to combine the cases of the forward Lag and the inverse Lag by switching the frequency of the bias power during the etching. In such case, the combinations of the switching frequencies include a combination of about 400 kHz and 13.56 MHz and a combination of about 2 MHz and 13.56 MHz, and there is no limit in the processing sequence for each combination as mentioned above.

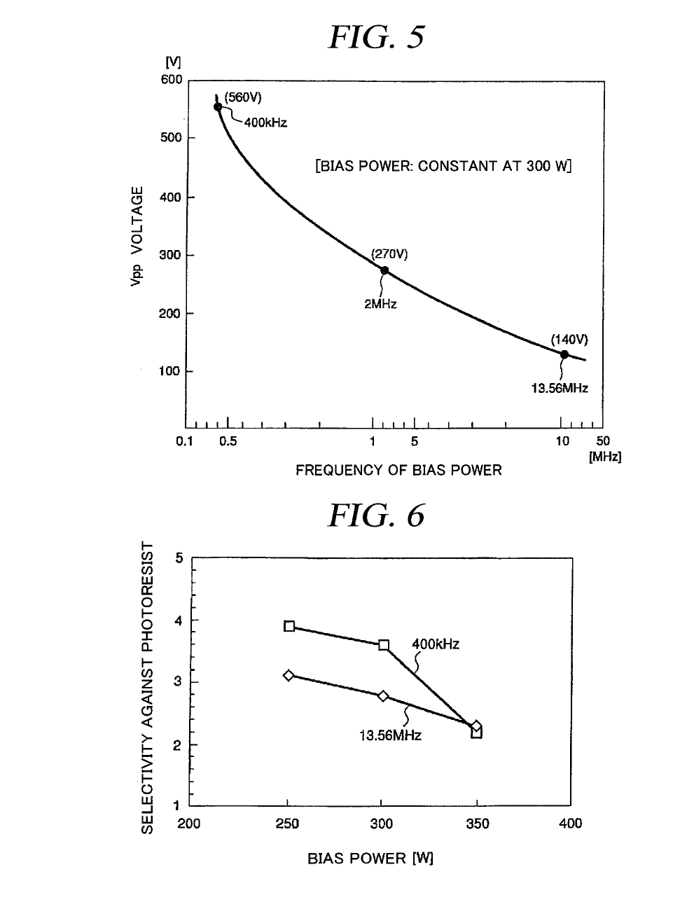

Further, FIG. 5 is a graph showing a relationship between the frequency of the bias power and a Vpp when the bias power is maintained constant. As can be seen from FIG. 5, the Vpp (peak-to-peak voltage) increases as the frequency of the high frequency bias power decreases. Accordingly, in general, as the Vpp gets smaller, the ion energy decreases and thus the selectivity against the etching stopper film increases. As a result, it can be confirmed that it is desirable to perform a conversion of the frequencies such that the frequency of the bias power is higher in the second step as a post-process than in the first step as a pre-process (the case shown in FIG. 2B). Moreover, the tendency of the graph shown in FIG. 5 is found the same regardless of the level of the bias power.

Moreover, if the etching is performed by using the bias power of about 2 MHz or 13.56 MHz for a long period of time, many stripes of prominences and depressions are formed on the sidewall inside the hole or trench so that the sidewall becomes rough, which is not desirable. Accordingly, as described above, the etching must be performed in two steps by switching the frequency of the bias power during the etching, and the bias power of about 400 kHz must be used in either one of the first and second steps.

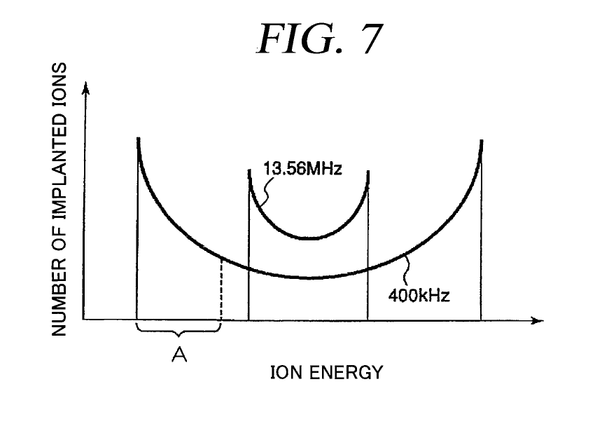

Now, there will be explained an improvement of the selectivity against the photoresist (mask) when the bias power of about 400 kHz is applied at a low power level. FIG. 6 is a graph showing a relationship between the bias power, the selectivity against the photoresist and the frequency of the bias power, and FIG. 7 is a graph showing ion energy distributions of the bias powers of about 400 kHz and 13.56 MHz.

As shown in FIG. 6, the bias powers of about 400 kHz and 13.56 MHz are herein examined. Though the selectivities against the photoresist film are identical at the power level of about 350 W, the selectivities gradually increase in both cases of 400 kHz and 13.56 MHz as the power is reduced, in particular, the selectivity becomes greater in case of 400 kHz. Especially, in case of 400 kHz, the selectivity is about 3.5 when the power is about 300 W. Accordingly, it can be seen that it is desirable to set the bias power to be of a frequency of about 400 kHz and a power level of about 300 W or below in order to obtain a selectivity of about 3.5 or above.

Moreover, the reason why the bias power of about 400 kHz is good with respect to the selectivity against the photoresist film is deemed to be as follows. That is, FIG. 7 presents a graph showing an ion energy distribution of each of the bias powers of about 400 kHz and 13.56 MHz, in which a vertical axis indicates the number of implanted ions. As can be seen from FIG. 7, the ion energy distribution is narrower in case of 13.56 MHz, while it gets enlarged in case of 400 kHz. In each case, the ion energy distribution is of a circular arc shape in which a central portion protruding downward becomes smaller, while its both ends become larger. As well known, in the plasma etching by the application of the bias power, the deposition and the etching are performed on the wafer alternately at a high speed due to the adhesion of active species and the ion implantation by the bias power, and the progression of the etching is determined by the total of them. In a left region A of 400 kHz in FIG. 7, the energy is so low that the etching does not occur, but only the adhesion (deposition) takes place. As a result, the etching does not progress on the surface of the photoresist, but only the deposition takes place thereon, so that the photoresist is seemingly in a non-etched state, and the selectivity against it can be maintained high.

Furthermore, the etching apparatus shown in FIG. 1 is nothing more than an example, and without being limited to this configuration, the present invention can be applied to, for example, a parallel plate type plasma etching apparatus, an ICP type plasma etching apparatus, and so forth. Further, here, though the semiconductor wafer is exemplified as the target object, the present invention is not limited thereto but can also be applied to, for example, a glass substrate, an LCD substrate, a ceramic substrate, and so forth.

What is claimed is:

1. An etching method for performing an etching process on an etching target film, which has a dielectric constant smaller than that of a SiO₂ film and formed on a surface of a target object, the method comprising:
mounting the target object on a mounting table in a processing vessel configured to be evacuable;
supplying a predetermined etching gas into the processing vessel and converting the etching gas into plasma; and
applying a high frequency power of a preset frequency to the mounting table as a bias power under the presence of the etching gas in plasma state,
wherein the step of applying the high frequency power as the bias power includes:
a first step of applying a high frequency power of a first frequency as the bias power; and
a second step of applying a high frequency power of a second frequency different from the first frequency as the bias power.

2. The etching method of claim 1, wherein a combination of the first frequency and the second frequency is a combination of a frequency equal to or smaller than about 2 MHz and a frequency greater than about 2 MHz.

3. The etching method of claim 1, wherein a combination of the first frequency and the second frequency is a combination of two kinds of frequencies selected from a group consisting of about 400 kHz, 2 MHz and 13.56 MHz, and the combination of frequencies includes the 400 kHz.

4. The etching method of claim 1, wherein one of the first and second steps is performed first and then the other step is performed.

5. The etching method of claim 1, wherein the high frequency power has a power equal to or less than about 300 W, and
a Vpp (peak-to-peak voltage) of the high frequency powers of the first and second frequencies is equal to or less than about 560 V.

6. The etching method of claim 1, wherein the etching gas is a CF-based gas, and
the etching gas contains at least one selected from a group consisting of CF₄, C₂F₆, C₃F₈ and CHF₃.

7. The etching method of claim 1, wherein the etching target film formed on the surface of the target object is formed of an interlayer dielectric, and
a mask, which is provided with a pattern for forming a groove portion and a hole portion in the interlayer dielectric, is provided on the interlayer dielectric.

8. The etching method of claim 7, wherein the hole portion has a transversal cross section of a circular shape, and
a width of the groove portion and a diameter of the hole portion are not greater than about 65 nm.

9. The etching method of claim 7, wherein an etching stopper film is formed under the interlayer dielectric, and
conditions are set up such that bottoms of the groove portion and the hole portion being formed in the interlayer dielectric reach the etching stopper film substantially at the same time.

10. The etching method of claim 7, wherein the interlayer dielectric is formed of a film selected from a group consisting of a SiOC film, a SiOCH film and a CF film.

11. The etching method of claim 9, wherein the interlayer dielectric is formed of a film selected from a group consisting of a SiOC film, a SiOCH film and a CF film, and
the etching stopper film is formed of a SiC film.

12. The etching method of claim 3, wherein, when applying the high frequency power of the frequency of about 400 kHz as the bias power, a power of the high frequency power is equal to or less than about 300 W.

13. The etching method of claim 4, wherein the frequency of the bias power in the other step performed later is higher than the frequency of the bias power in the one step performed first.

14. The etching method of claim 9, wherein the conditions are set up such that the bottoms of the groove portion and the hole portion being formed in the interlayer insulating film reach the etching stopper film approximately at the same time by performing one of the first and second steps first and then performing the other step and by switching from the one step to the other step at an appropriate timing.

15. An etching apparatus comprising:
a processing vessel incorporating therein a mounting table for mounting thereon a target object having an etching target film, which has a dielectric constant smaller than that of a SiO₂ film, formed on a surface thereof;
a gas exhaust system for evacuating the inside of the processing vessel;
a gas supply unit for supplying an etching gas into the processing vessel;
a plasma generating unit for generating plasma in the processing vessel;
a high frequency bias power supply unit for supplying a high frequency power of a first frequency and a high frequency power of a second frequency different from the first frequency as a bias power to the mounting table; and
a control unit for controlling the high frequency bias power supply unit,
wherein the control unit controls the high frequency bias power supply unit such that the high frequency bias power supply unit performs:
a first process of applying the high frequency power of the first frequency as the bias power; and
a second process of applying the high frequency power of the second frequency different from the first frequency as the bias power.

16. A computer program for executing an etching method, on a computer, for performing an etching process on an etching target film, which has a dielectric constant smaller than that of a SiO₂ film and formed on a surface of a target object, the method comprising:
mounting the target object on a mounting table in a processing vessel configured to be evacuable;
supplying a predetermined etching gas into the processing vessel and converting the etching gas into plasma; and
applying a high frequency power of a preset frequency to the mounting table as a bias power under the presence of the etching gas in plasma state,
wherein the step of applying the high frequency power as the bias power includes:
a first step of applying a high frequency power of a first frequency as the bias power; and
a second step of applying a high frequency power of a second frequency different from the first frequency as the bias power.

17. A storage medium for storing therein a computer program for executing an etching method, on a computer, for performing an etching process on an etching target film, which has a dielectric constant smaller than that of a SiO₂ film and formed on a surface of a target object, the method comprising:
mounting the target object on a mounting table in a processing vessel configured to be evacuable;
supplying a predetermined etching gas into the processing vessel and converting the etching gas into plasma; and
applying a high frequency power of a preset frequency to the mounting table as a bias power under the presence of the etching gas in plasma state,
wherein the step of applying the high frequency power as the bias power includes:
a first step of applying a high frequency power of a first frequency as the bias power; and
a second step of applying a high frequency power of a second frequency different from the first frequency as the bias power.
